(19) United States
(12) Patent Application Publication
(10) Pub. No.: US 2026/0251935 A1
(43) Pub. Date: Aug. 27, 2026

(54) DISPLAY APPARATUS

(71) Applicant: LG Display Co., Ltd., Seoul (KR)

(72) Inventors: Hyukkyu KWON, Paju-si (KR); Taemin LIM, Paju-si (KR)

(21) Appl. No.: 19/424,117

(22) Filed: Dec. 18, 2025

(30) Foreign Application Priority Data
Feb. 26, 2025 (KR) 10-2025-0024781

(51) Int. Cl. G02F 1/13357; F21V 8/00

(52) U.S. Cl. CPC G02F 1/133603; G02B 6/0035; G02F 1/133606

(57) ABSTRACT

A display apparatus including a display area including a first display area and a second display area disposed in a first direction, a plurality of first light sources disposed within the display area, a diffusion sheet disposed on the plurality of first light sources, a light control film disposed on the diffusion sheet, a light guide plate disposed on the light control film and including a base substrate, a first light guide pattern and a second light guide pattern disposed on the base substrate, and a plurality of second light sources disposed to face side surfaces of the light guide plate. The first light guide pattern and the second light guide pattern have different shapes, the first light guide pattern is disposed in the first display area, and the second light guide pattern is disposed in the second display area.

### CROSS REFERENCE TO RELATED APPLICATION

This application claims priority from and the benefit of Korean Patent Application No. 10-2025-0024781, filed on February 26, 2025, which is hereby incorporated by reference for all purposes as if fully set forth herein.

### BACKGROUND

### FIELD

Embodiments of the invention relate generally to a display apparatus.

### DISCUSSION OF THE BACKGROUND

As the information society develops, various demands for display apparatuses for displaying images are increasing, and various types of display apparatuses, such as a liquid crystal display (LCD) apparatus and an organic light-emitting diode (OLED) display apparatus, are being utilized.

The conventional display apparatuses do not limit a viewing angle. However, for privacy and information protection reasons, restrictions on a viewing angle have been increasingly required recently. For example, a display apparatus used as an in-vehicle information medium may provide high-quality images to a front-seat passenger, but it is desirable to limit a viewing angle for a driver for the sake of driving safety.

The above information disclosed in this Background section is only for understanding of the background of the inventive concepts, and, therefore, it may contain information that does not constitute prior art.

### SUMMARY

Display apparatuses according to embodiments of the invention are capable of displaying different images according to a viewing angle.

Embodiments of the invention are also directed to providing a display apparatus in which light guide patterns with different characteristics depending on a viewing angle may be disposed.

Embodiments of the invention are also directed to providing a display apparatus in which light guide patterns with different characteristics depending on the viewing angle may be disposed, thereby improving the quality of images emitted at both narrow and wide viewing angles.

Additional features of the inventive concepts will be set forth in the description which follows, and in part will be apparent from the description, or may be learned by practice of the inventive concepts.

According to one or more embodiments of the invention, a display apparatus includes a display area including a first display area and a second display area disposed in a first direction, a plurality of first light sources disposed within the display area, a diffusion sheet disposed on the plurality of first light sources, a light control film disposed on the diffusion sheet, a light guide plate on the light control film and including a base substrate, a first light guide pattern and a second light guide pattern on the base substrate, and a plurality of second light sources disposed to face side surfaces of the light guide plate. The first light guide pattern and the second light guide pattern have different shapes, the first light guide pattern is disposed in the first display area, and the second light guide pattern is disposed in the second display area.

The first light guide pattern may cover the entire first display area of the base substrate, and the second light guide pattern may cover a portion of the second display area of the base substrate and expose the remaining portion.

The second light guide pattern may be disposed near an end portion of at least one of one side and the other side of the base substrate in a second direction intersecting the first direction.

The second light guide pattern may extend from the end portion of the base substrate in the second direction, and a cross-sectional size of the second light guide pattern in the first direction may decrease farther from the end portion of the base substrate.

A cross-sectional size of the first light guide pattern in the first direction may be constant in the second direction.

The second light guide pattern may be provided as a plurality of second light guide patterns and repeatedly disposed in the first direction.

The first light guide pattern is provided as a plurality of first light guide patterns and repeatedly disposed in the first direction, and each of the plurality of first light guide patterns extends in the second direction.

The first display area may operate in a share mode with a wide viewing angle, and the second display area may variously operate between the share mode with the wide viewing angle and a privacy mode with a narrow viewing angle.

When the second display area operates in a share mode, some of the plurality of second light sources corresponding to the second display area may be turned on and, when the second display area operates in the privacy mode, some of the plurality of second light sources corresponding to the second display area may be turned off.

The plurality of second light sources may be repeatedly disposed in the first direction and disposed to face a side surface of at least one of one side and the other side of the light guide plate in the second direction, and the second direction may intersect the first direction.

The first light guide pattern and the second light guide pattern may be disposed on an upper surface of the base substrate.

The display apparatus may further include a third light guide pattern disposed on a side surface of the base substrate. The third light guide pattern may be provided as a plurality of third light guide patterns, repeatedly disposed in a thickness direction of the light guide plate, and extending in the first direction.

The plurality of third light guide patterns may face the plurality of second light sources.

The display apparatus may further include a third display area in which a display boundary, which is a boundary between the first display area and the second display area, may move in the first direction.

The third display area may overlap at least one of the first display area and the second display area.

The second light guide pattern may be disposed across the third display area and the second display area.

According to yet another embodiment of the invention, a display apparatus includes a display area including a first display area and a second display area, a plurality of first light sources disposed within the display area, a diffusion sheet disposed on the plurality of first light sources, a light control film disposed on the diffusion sheet, a base substrate disposed on the light control film, a light guide plate disposed on the base substrate and including a first light guide pattern and a second light guide pattern, and a plurality of second light sources disposed to face side surfaces of the light guide plate. The first light guide pattern is disposed in the first display area, the second light guide pattern is disposed in the second display area, and the second light guide pattern covers a portion of the second display area of the base substrate and exposes the remaining portion.

The first light guide pattern may cover the entire first display area of the base substrate.

The first light guide pattern and the second light guide pattern may have different shapes.

The first display area may operate in a share mode with a wide viewing angle, and the second display area may variously operate between the share mode with the wide viewing angle and a privacy mode with a narrow viewing angle.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view of a display apparatus according to one embodiment.

FIG. 2 is an exploded perspective view of the display apparatus according to one embodiment.

FIG. 3 is a cross-sectional view along line A-A’ in FIG. 1.

FIG. 4 is a schematic view of the display apparatus in which both a first display area and a second display area operate in a share mode.

FIG. 5 is a schematic view of the display apparatus in which the first display area operates in the share mode and the second display area operates in a privacy mode.

FIG. 6 is a perspective view of a second light guide plate and its surroundings according to one embodiment.

FIG. 7 and FIG. 8 are enlarged views showing a portion of the second display area of FIG. 6.

FIG. 9 is a cross-sectional view along line B-B’ in FIG. 6.

FIG. 10 is a schematic view showing a fourth light guide pattern according to one embodiment.

FIG. 11 is a graph showing the density of the fourth light guide pattern in a second direction according to one embodiment.

FIG. 12 is a plan view of a display apparatus according to another embodiment.

FIG. 13 is a perspective view of a second light guide plate and its surroundings according to another embodiment.

FIG. 14 is a plan view of the display apparatus according to another embodiment.

FIG. 15 is a perspective view of a second light guide plate and its surroundings according to still another embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z – axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

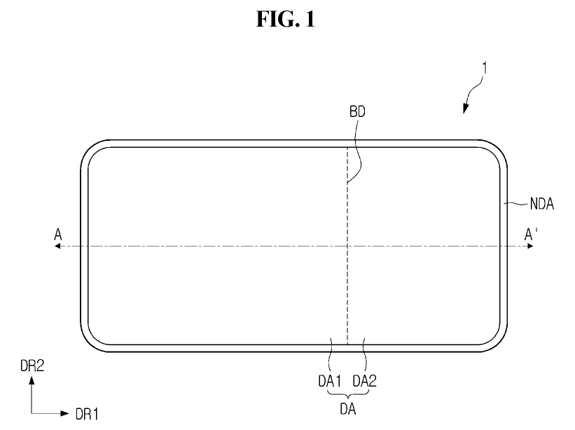

FIG. 1 is a plan view of a display apparatus according to one embodiment.

Referring to FIG. 1, a display apparatus 1 may include both a display function of displaying an image and a touch sensing function of sensing a user’s touch, but is not limited thereto. For example, the display apparatus 1 may include only one of the display function of displaying an image and the touch sensing function of sensing a user’s touch.

The display apparatus 1 may be an electroluminescent display apparatus or a micro light-emitting diode display apparatus that includes a touch sensor. Alternatively, the electroluminescent display apparatus including a touch sensor may be an organic light-emitting diode (OLED) display apparatus, a quantum-dot light-emitting diode display apparatus, or an inorganic light-emitting diode display apparatus.

The display apparatus 1 according to the present embodiment may be a vehicle display apparatus, but is not limited thereto. For example, the description of the display apparatus 1 may be applied without limitation to the type of the apparatus as long as a display apparatus is an apparatus including a display function.

The display apparatus 1 may have a length extending in a first direction DR1 and have a width in a second direction DR2. The first direction DR1 and the second direction DR2 may intersect each other or may be perpendicular, but are not limited thereto. The display apparatus 1 may have a long side extending in the first direction DR1 and a short side extending in the second direction DR2.

When the display apparatus 1 according to the present embodiment is a vehicle display apparatus, the display apparatus 1 may include a function of manipulating at least some of various functions of a vehicle, a function of displaying various information about the vehicle, etc.

When the display apparatus 1 according to the present embodiment is a vehicle display apparatus, the display apparatus 1 may be disposed on a dashboard of a vehicle. The display apparatus 1 may be disposed across a driver’s seat and a front passenger’s seat that are disposed at front seats of a vehicle, but is not limited thereto.

A direction in which the display apparatus 1 is disposed to cross the driver’s seat and the front passenger’s seat may correspond to the first direction DR1. That is, the display apparatus 1 may extend in the first direction DR1 and may be disposed across the driver’s seat and the front passenger’s seat in the first direction DR1.

When the display apparatus 1 is a vehicle display apparatus, both a driver DRIVER sitting in the driver’s seat and a passenger CO-DRIVER sitting in the front passenger’s seat may use the display apparatus 1. The display apparatus 1 may provide the same image to both the driver DRIVER sitting in the driver’s seat and the front passenger CO-DRIVER sitting in the front passenger’s seat or provide different images to each.

The display apparatus 1 may include a display area DA and a non-display area NDA.

The display area DA may be an area in which an image may be displayed. Light may be emitted externally from the display area DA. The display area DA may further include a function of sensing a user’s touch. In this case, the display area DA may correspond to a touch sensing area, but is not limited thereto.

A planar shape of the display area DA may correspond to the planar shape of the display apparatus 1, but is not limited thereto. The display area DA may have a long side extending in the first direction DR1 and a short side extending in the second direction DR2.

The display area DA may include a first display area DA1 and a second display area DA2. The first display area DA1 and the second display area DA2 may be disposed continuously in the first direction DR1. That is, the second display area DA2 may be disposed at one side of the first display area DA1 in the first direction DR1, and the first display area DA1 may be disposed at the other side of the second display area DA2 in the first direction DR1.

The first display area DA1 may operate in a first mode, and the second display area DA2 may operate in both the first mode and a second mode.

For example, the first mode may be a share mode, which does not limit a side viewing angle of the display apparatus 1. The second mode may be a privacy mode, which limits the side viewing angle of the display apparatus 1. That is, the share mode may have a wide viewing angle, and the privacy mode may have a narrow viewing angle.

Here, the side viewing angle may be a side viewing angle in the first direction DR1.

The first display area DA1 may maintain the share mode during the operation of the display apparatus 1. The second display area DA2 may selectively operate in the share mode and the privacy mode during the operation of the display apparatus 1. During the operation of the display apparatus 1, the second display area DA2 may change from the share mode to the privacy mode or from the privacy mode to the share mode.

When the display apparatus 1 is applied to a vehicle display apparatus, the first display area DA1 may be disposed at a location near the driver’s seat, and the second display area DA2 may be disposed at a location near the front passenger’s seat.

When each of the first display area DA1 and the second display area DA2 operates in the share mode, images, videos, and the like displayed in the first display area DA1 and images, videos, and the like displayed in the second display area DA2 may be provided to both the driver sitting in the driver’s seat and the front passenger sitting in the front passenger’s seat.

When the second display area DA2 operates in the privacy mode, the images, videos, and the like displayed in the second display area DA2 may be provided to the front passenger sitting in the front passenger’s seat and may not be provided to the driver sitting in the driver’s seat.

A display boundary BD, which is a virtual line, may be positioned between the first display area DA1 and the second display area DA2. The display boundary BD may be a boundary between the first display area DA1 and the second display area DA2. The second display area DA2 may be positioned at one side of the display boundary BD in the first direction DR1, and the first display area DA1 may be positioned at the other side of the display boundary BD in the first direction DR1.

The non-display area NDA may be an area in which no image is displayed. Light may not be emitted externally from the non-display area NDA, but is not limited thereto. The non-display area NDA may be located around the display area DA. The non-display area NDA may surround the display area DA, but the embodiments of the invention are not limited thereto. A bezel area of the display apparatus 1 may be defined by the non-display area NDA, but the embodiments of the invention are not limited thereto.

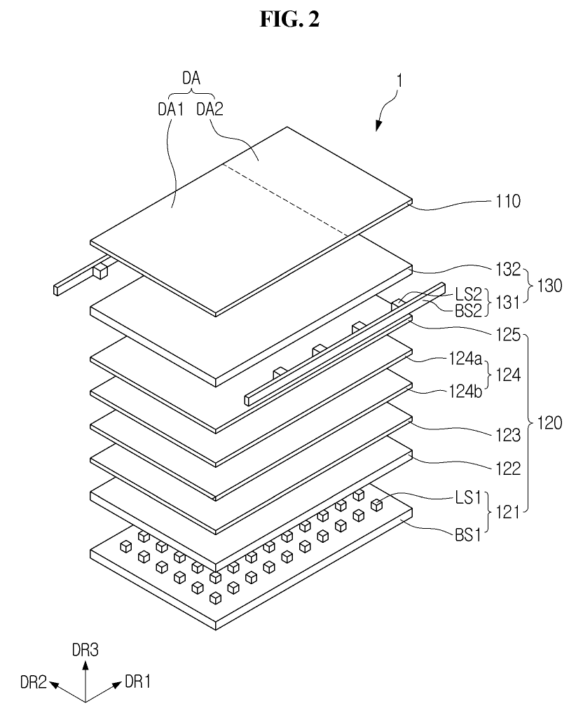

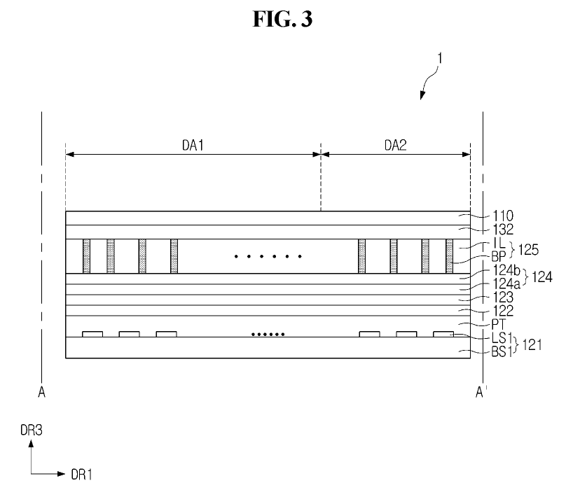

FIG. 2 is an exploded perspective view of the display apparatus according to one embodiment. FIG. 3 is a cross-sectional view along line A-A’ in FIG. 1.

Referring to FIGS. 1 to 3, the display apparatus 1 according to one embodiment may include a display panel 110 that includes pixels and displays images, and first and second backlight units 120 and 130 that are disposed on a back surface of the display panel 110 and emit light to a front surface of the display panel 110. Although not shown, the display apparatus 1 may further include a panel guide, a top case, a bottom cover, and the like that fixedly store the display panel 110 and the first and second backlight units 120 and 130.

The display panel 110 may be a liquid crystal panel and may include a lower substrate and an upper substrate bonded to face each other, and a liquid crystal layer interposed between the lower and upper substrates.

The lower substrate may include gate lines and data lines arranged to intersect each other, and liquid crystal cells formed at intersections of the gate lines and the data lines. The liquid crystal cells may include thin film transistors disposed at the intersections of the gate lines and the data lines, and a pixel electrode that receives a data voltage applied to the data line through the thin film transistor when the thin film transistor is turned on.

On the upper substrate, color filters for implementing multiple colors by including red, green, and blue, a black matrix for dividing the color filters and blocking light passing through the liquid crystal layer, and a common electrode for applying voltage to the liquid crystal layer.

The liquid crystal cells are driven by an electric field generated by a potential difference between data voltages supplied to the pixel electrodes through the data lines and a common voltage supplied to the common electrode, thereby controlling the amount of light passing through the display panel 110.

The first and second backlight units 120 and 130 are disposed below the display panel 110 and provide light to the display panel 110. The first backlight unit 120 may be disposed below the display panel 110, and the second backlight unit 130 may be disposed between the first backlight unit 120 and the display panel 110.

The first backlight unit 120 may include a first light source package 121, a first light guide plate 122, a diffusion sheet 123, a prism sheet 124, and a light control film 125.

Planar shapes of the first light guide plate 122, the diffusion sheet 123, the prism sheet 124, and the light control film 125 may correspond to the planar shape of the display apparatus 1. That is, the first light guide plate 122, the diffusion sheet 123, the prism sheet 124, and the light control film 125 may have long sides extending in the first direction DR1 and short sides extending in the second direction DR2.

The first light source package 121 may include a first light source LS1 and a first light source substrate BS1. The first light source LS1 may be provided as a plurality of first light sources, and the plurality of first light sources LS1 may be mounted on the first light source substrate BS1. The plurality of first light sources LS1 may be repeatedly disposed in the first direction DR1 and the second direction DR2 on the first light source substrate BS1. At least some of the plurality of first light sources LS1 may be disposed in the display area DA.

The plurality of first light sources LS1 may be driven by receiving power through the first light source substrate BS1 and may generate light. Although not limited thereto, the first light source LS1 may generate light using various light sources, such as a cold cathode fluorescent lamp (CCFL), an external electrode fluorescent lamp (EEFL), a hot cathode fluorescent lamp (HCFL), a light emitting diode (LED), etc.

The first light source substrate BS1 may provide a space in which the first light source LS1 may be disposed. The first light source substrate BS1 may have a circuit board mounted thereon for the operation of the first light source LS1. The first light source substrate BS1 may control the first light source LS1 according to electrical signals supplied through wirings of the circuit board, thereby allowing the first light source LS1 to emit light.

The first light source package 121 may be disposed below the first light guide plate 122. Accordingly, light emitted from the first light source package 121 may be incident on a lower surface of the first light guide plate 122. However, the arrangement of the first light source package 121 is not limited thereto. For example, the first light source package 121 may be disposed on one side surface of the first light guide plate 122. That is, the first light source package 121 may be disposed to face one side surface of the first light guide plate 122. Accordingly, the light emitted from the first light source package 121 may be incident on a side surface of the first light guide plate 122 and emitted to an upper surface of the first light guide plate 122.

The display apparatus 1 may further include a light source protection layer PT. The light source protection layer PT may be disposed on the first light source package 121 and disposed to cover the first light source LS1. The light source protection layer PT can protect the first light sources LS1. The light source protection layer PT may be formed of a resin, but is not limited thereto.

The first light guide plate 122 may be disposed on the first light source package 121. The first light guide plate 122 is disposed to face the first light source package 121 and guides the light incident from the first light source package 121 to be emitted upward.

material, for example, a plastic material such as polymethyl methacrylate (PMMA) or a material selected from polycarbonate (PC)-based materials. However, the material of the first light guide plate 122 is not limited to the above materials, and the first light guide plate 122 may be formed of other materials.

The diffusion sheet 123 may be disposed on the first light guide plate 122. The diffusion sheet 123 diffuses the light emitted from the first light guide plate 122, thereby improving brightness uniformity depending on a viewing angle. The diffusion sheet 123 may be formed of a PET or PC resin and may include a particle coating layer that serves as a diffuser.

The prism sheet 124 may be disposed on the diffusion sheet 123. The prism sheet 124 condenses the light emitted from the first light guide plate 122 or the diffusion sheet 123 so that a traveling direction of light is close to a normal direction of the display panel 110, thereby improving the front brightness of the display panel 110.

The prism sheet 124 may include a first prism sheet 124a and a second prism sheet 124b. Each of the first prism sheet 124a and the second prism sheet 124b may include a prism pattern. A prism pattern of the first prism sheet 124a and a prism pattern of the second prism sheet 124b may have axes that are orthogonal to each other.

Since a second light source package 131 is disposed on one side and the other side of a second light guide plate 132 in the second direction DR2 and the prism sheet 124 includes the first prism sheet 124a and the second prism sheet 124b, the brightness of the display apparatus 1 can be improved.

A light control film (LCF) 125 may be disposed on the prism sheet 124. The light control film 125 may control a light emission profile of the first backlight unit 120. For example, the light control film 125 may adjust view angles of the light emitted from the first backlight unit 120 in a left-right direction (first direction DR1) and/or vertical direction (second direction DR2) to narrow viewing angles.

The light control film 125 may include a plurality of light-shielding patterns BP and patterned insulating films IL that fill spaces between the light-shielding patterns BP. Although not shown, the light control film 125 may further include a lower substrate and an upper substrate with the light-shielding patterns BP and the patterned insulating films IL interposed therebetween.

The light-shielding patterns BP may include a black dye, such as carbon black. The light-shielding patterns BP may have a predetermined thickness in a thickness direction (third direction DR3) and extend parallel to the second direction DR2. The light-shielding pattern BP may be provided as a plurality of light-shielding patterns and repeatedly disposed in the first direction DR1.

A distance between adjacent light-shielding patterns BP may be constant throughout the display area DA, but is not limited thereto. The plurality of light-shielding patterns BP may all have the same thickness, but are not limited thereto.

For example, the distance between adjacent light-shielding patterns BP and the thickness of the plurality of light-shielding patterns BP may be the same across the first display area DA1 and the second display area DA2, but are not limited thereto.

Accordingly, when the distance between adjacent light-shielding patterns BP is constant across the entire area and the plurality of light-shielding patterns BP all have the same thickness, the light control film 125 can more smoothly limit an emission angle of the light emitted from the first light source package 121 so that the traveling direction may be set to form a narrow angle. Furthermore, in this case, a more uniform amount of light can be provided across the entire display area DA, thereby improving clarity across the entire display area DA.

A traveling path of the light passing through the light control film 125 may be limited by the light-shielding pattern BP. The light control film 125 may adjust the transmittance of the light emitted from the first light source package 121 and emit the light, thereby enhancing the contrast and clarity of images, videos, and the like displayed in the display area DA.

Furthermore, the light control film 125 may limit the emission angle of the light emitted from the first light source package 121 using the light-shielding pattern BP.

The traveling path of the light passing through the light control film 125 may be limited by the light-shielding pattern BP. The light control film 125 can suppress or prevent the light emitted from the first light source package 121 from traveling to one side or the other side in the first direction DR1 using the light-shielding pattern BP.

Among the light emitted from the first light source package 121, light traveling in the third direction DR3 and traveling to one side or the other side in the first direction DR1 may be blocked by the light control film 125. Accordingly, the traveling direction of the light, which is emitted from the first light source package 121 and passes through the light control film 125, has a narrow angle.

Accordingly, most of the light emitted from the first light source package 121 in the first display area DA1 may travel toward the driver, and most of that light may not be perceived by the front passenger. Most of the light emitted from the first light source package 121 in the second display area DA2 may travel toward the front passenger, and most of that light may not be perceived by the driver.

The second backlight unit 130 may be disposed on the first backlight unit 120. The second backlight unit 130 may include the second light source package 131 and the second light guide plate 132.

The second light guide plate 132 may be disposed on the light control film 125. The second light guide plate 132 guides light emitted from the second backlight unit 130 and emits the light upward. The light emitted from the second backlight unit 130 may be incident on side surfaces of the second light guide plate 132.

The planar shape of the second light guide plate 132 may correspond to the planar shape of the display apparatus 1. That is, the second light guide plate 132 may have a long side extending in the first direction DR1 and a short side extending in the second direction DR2.

The second light guide plate 132 may be formed of substantially the same material as the first light guide plate 122, but is not limited thereto.

The second light source package 131 may be disposed on the side surfaces of the second light guide plate 132. The second light source package 131 may be disposed to face (or be opposite to) the long side of the second light guide plate 132. The second light source package 131 may extend in the first direction DR1.

The second light source package 131 may be disposed on both one side and the other side of the second light guide plate 132 in the second direction DR2, but is not limited thereto. That is, the second light guide plate 132 may be disposed between the second light source packages 131. The second light source packages 131 may be disposed to face each other with the second light guide plate 132 interposed therebetween.

The second light source package 131 may include a second light source LS2 and a second light source substrate BS2. The second light source substrate BS2 may extend in the first direction DR1. The second light source LS2 may be provided as a plurality of second light sources, and the plurality of second light sources LS2 may be mounted on the second light source substrate BS2. The plurality of second light sources LS2 may be disposed on the second light source substrate BS2 and may be repeatedly disposed in the first direction DR1.

In FIG. 2, for convenience of description, only four second light sources LS2 disposed on the second light source substrate BS2 are shown, but the embodiments of the invention are not limited thereto, and four or more second light sources LS2 may be provided.

As the plurality of second light sources LS2 are repeatedly disposed in the first direction DR1, the viewing angle in the first direction DR1 in the share mode can be improved.

The plurality of second light sources LS2 may be driven by receiving power through the second light source substrate BS2 and may generate light. Although not limited thereto, the second light source LS2 may generate light using various light sources, such as a CCFL, an EEFL, an HCFL, an LED, etc.

The second light source substrate BS2 may provide a space in which the second light source LS2 may be disposed. The second light source substrate BS2 may have a circuit board mounted thereon for the operation of the second light source LS2. The second light source substrate BS2 may control the second light source LS2 according to electrical signals supplied through wirings of the circuit board, thereby allowing the second light source LS2 to emit light.

The second light guide plate 132 may refract the incident light emitted from the second light source package 131 both in the second direction DR2 and the first direction DR1. Accordingly, the light emitted from the second light source package 131 and passing through the second light guide plate 132 may realize the share mode in at least a portion of the display apparatus 1.

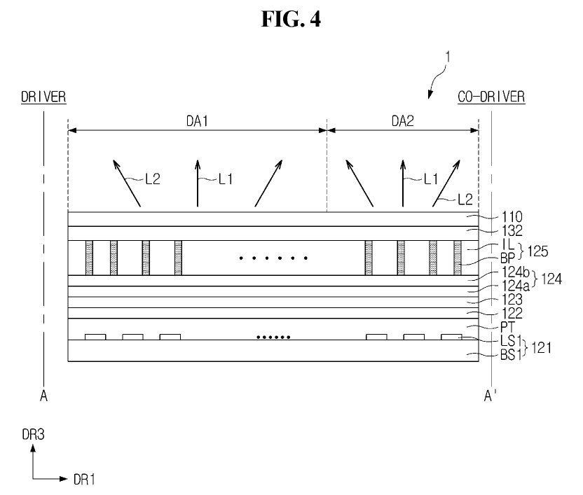

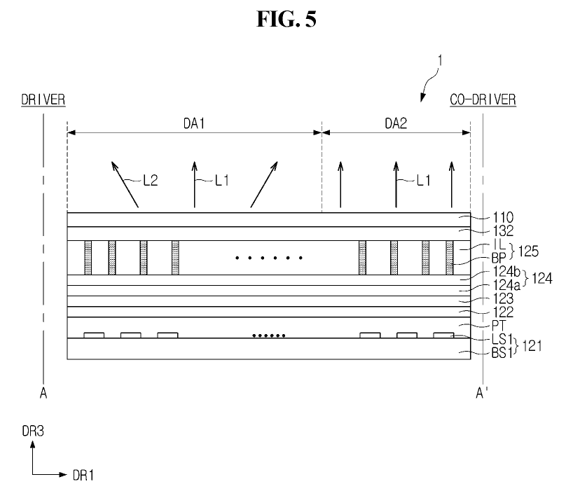

FIG. 4 is a schematic view of the display apparatus in which both a first display area and a second display area operate in a share mode. FIG. 5 is a schematic view of the display apparatus in which the first display area operates in the share mode and the second display area operates in a privacy mode.

The light that is emitted from the first light source package 121 and passes through the light control film 125 has a narrow viewing angle. Accordingly, when there is no light emitted from the second light source package 131, both the first display area DA1 and the second display area DA2 operate in the privacy mode.

The plurality of second light sources LS2 may all be turned on and off independently. Accordingly, when at least some of the plurality of second light sources LS2 are turned on, a portion of the display area DA corresponding to the area in which the turned-on second light source LS2 is disposed may be switched to the share mode.

As shown in FIG. 4, when the second light sources LS2 disposed in the areas corresponding to the first display area DA1 and the second display area DA2 are turned on and emit light, the first display area DA1 and the second display area DA2 may emit both light L1 with a narrow viewing angle, which is emitted from the first light source package 121 and passes through the light control film 125, and light L2 with a wide viewing angle in the first direction DR1, which is emitted from the second light source package 131 and passes through the second light guide plate 132.

Accordingly, both the first display area DA1 and the second display area DA2 operate in the share mode.

As shown in FIG. 5, some of the second light sources LS2 disposed in the area corresponding to the first display area DA1 may be turned on to emit light, and the remaining ones of the second light sources LS2 disposed in the area corresponding to the second display area DA2 may be turned off so as not to emit light.

In this case, the first display area DA1 may emit both the light L1 with a narrow viewing angle, which is emitted from the first light source package 121 and passes through the light control film 125, and the light L2 with a wide viewing angle in the first direction DR1, which is emitted from the second light source package 131 and passes through the second light guide plate 132. The second display area DA2 may emit only the light L1 with a narrow viewing angle, which is emitted through the light control film 125 and passes through the second light guide plate 132.

Accordingly, the first display area DA1 operates in the share mode, and the second display area DA2 operates in the privacy mode.

When the first display area DA1 operates only in the share mode, the first light sources LS1 and the second light sources LS2 disposed in the area corresponding to the first display area DA1 may be maintained in the turned-on state.

Here, the first light sources LS1 disposed in the area corresponding to the first display area DA1 may be the first light sources LS1 disposed in the first display area DA1 in the third direction DR3.

The second light sources LS2 disposed in the area corresponding to the first display area DA1 may be the second light sources LS2 disposed on one side and the other side of the first display area DA1 in the second direction DR2.

When the second display area DA2 operates variably between the share mode and the privacy mode, the first light sources LS1 disposed in the area corresponding to the second display area DA2 may be maintained in the turned-on state, and the second light sources LS2 disposed in the area corresponding to the second display area DA2 may be switched between the turned-on state and the turned-off state. As the second light sources LS2 disposed in the area corresponding to the second display area DA2 are switched between the turned-on and turned-off states, the share mode and privacy mode of the second display area DA2 may be switched.

Here, the first light sources LS1 disposed in the area corresponding to the second display area DA2 may be the first light sources LS1 disposed in the second display area DA2 in the third direction DR3. The second light sources LS2 disposed in the area corresponding to the second display area DA2 may be the second light sources LS2 disposed on one side and the other side of the second display area DA2 in the second direction DR2.

Since the display apparatus 1 includes both the first display area DA1 and the second display area DA2, the driver and the front passenger may receive different images depending on their viewing angles.

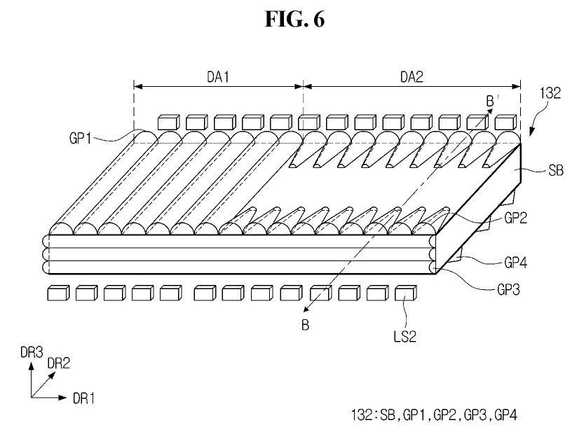

In the first display area DA1 and the second display area DA2, different light guide patterns GP1 to GP4 (see FIG. 6) may be disposed on the second light guide plate 132. Accordingly, in the first display area DA1, which operates only in the share mode, the wide viewing angle characteristics in the first direction DR1 can be improved, and in the second display area DA2, which operates variably between the share and privacy modes, both the wide viewing angle characteristics and the narrow viewing angle characteristics can be improved. Accordingly, the quality of images emitted at both the wide viewing angle and the narrow viewing angle can be improved.

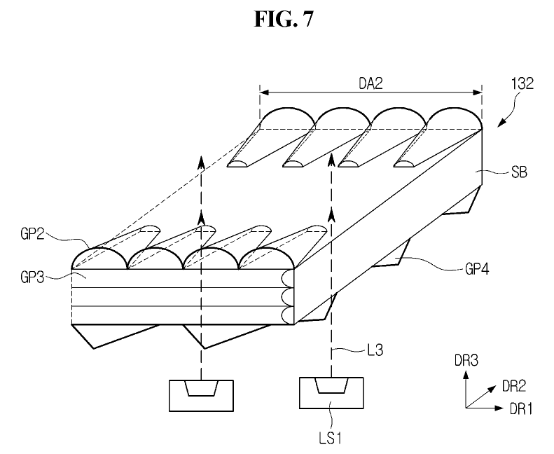

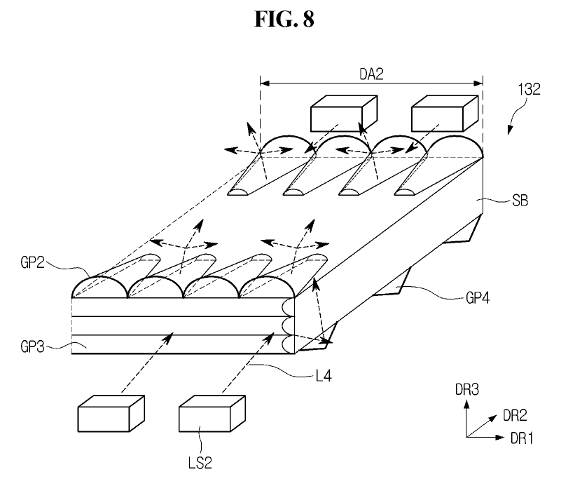

FIG. 6 is a perspective view of a second light guide plate and its surroundings according to one embodiment. FIGS. 7 and 8 are enlarged views showing a portion of the second display area of FIG. 6.

FIG. 7 schematically shows a traveling direction of light when the second display area DA2 operates in the privacy mode. FIG. 8 schematically shows a traveling direction of light when the second display area DA2 operates in the share mode.

Referring to FIGS. 1 to 3 and 6 to 8, the light guide patterns GP1 and GP2 having different shapes may be disposed in the first display area DA1 and the second display area DA2 of the second light guide plate 132, respectively.

Specifically, the second light guide plate 132 may include a base substrate SB, and a first light guide pattern GP1, a second light guide pattern GP2, a third light guide pattern GP3, and a fourth light guide pattern GP4 that are disposed on the base substrate SB.

The first light guide pattern GP1 and the second light guide pattern GP2 may be disposed on an upper surface of the base substrate SB. The upper surface of the base substrate SB may be a surface facing the display panel 110. The upper surface of the base substrate SB may be a surface from which light is emitted.

The first light guide pattern GP1 and the second light guide pattern GP2 may have different shapes and may be disposed in different areas. The first light guide pattern GP1 may be disposed in the first display area DA1, and the second light guide pattern GP2 may be disposed in the second display area DA2.

The first light guide pattern GP1 may protrude from the base substrate SB toward the display panel 110. The first light guide pattern GP1 may be provided as a plurality of first light guide patterns. Each of the plurality of first light guide patterns GP1 may extend in the second direction DR2. In the first display area DA1, the plurality of first light guide patterns GP1 may be repeatedly disposed in the first direction DR1.

A cross section of the first light guide pattern GP1 in the second direction DR2 may have a convex shape toward the display panel 110. A cross section of the first light guide pattern GP1 in the first direction DR1 may have a circular shape. The cross section of the first light guide pattern GP1 in the first direction DR1 may have one selected from a partial shape of a circle, an ellipse, etc.

The cross section of the first light guide pattern GP1 in the first direction DR1 may be constant in the second direction DR2. The first light guide pattern GP1 may extend in the second direction DR2, and the cross-sectional size of the first light guide pattern GP1 may be constant in the second direction DR2.

The first light guide pattern GP1 may extend in the second direction DR2, and a thickness (width) of the first light guide pattern GP1 may be constant in the second direction DR2. Here, the thickness of the first light guide pattern GP1 may be a thickness in the third direction DR3.

That is, the first light guide pattern GP1 may be disposed across the entirety of the first display area DA1. The entirety of the first display area DA1 of the base substrate SB may be covered by the first light guide pattern GP1.

The first light guide pattern GP1 can uniformly diffuse light incident from the first light source LS1 and light incident from the second light source LS2 in the first direction DR1 through scattering, refraction, diffraction, total surface reflection, etc.

Since the first light guide pattern GP1 is disposed over the entirety of the first display area DA1 and has a constant cross-sectional shape in the second direction DR2, light that has passed through the first light guide pattern GP1 can be more smoothly diffused in the first direction DR1. Accordingly, when the first display area DA1 is driven in the share mode, a wider viewing angle can be secured, and the image emitted at the wide viewing angle can have more uniform brightness.

The second light guide pattern GP2 may protrude from the base substrate SB toward the display panel 110. The second light guide pattern GP2 may be provided as a plurality of second light guide patterns.

The second light guide pattern GP2 may be disposed near (or adjacent to) an end of at least one of one side and the other side of the base substrate SB in the second direction DR2. For example, when the second light source LS2 may be disposed on both one side and the other side of the second light guide plate 132 in the second direction DR2, the second light guide pattern GP2 may be disposed near both the ends of the one side and the other side of the base substrate SB in the second direction DR2.

In the second display area DA2, the second light guide pattern GP2 may be repeatedly disposed in the first direction DR1 near the end portions of the one side and the other side of the base substrate SB in the second direction DR2.

A length of the second light guide pattern GP2 in the second direction DR2 may be less than a length of the first light guide pattern GP1 in the second direction DR2. The length of the second light guide pattern GP2 in the second direction DR2 may be less than a length of the base substrate SB in the second direction DR2.

Accordingly, the base substrate SB between the second light guide pattern GP2 disposed near the end portion of the one side of the base substrate SB in the second direction DR2 and the second light guide pattern GP2 disposed near the end portion of the other side of the base substrate SB in the second direction DR2 may be exposed without being covered by the second light guide pattern GP2.

A cross section of the second light guide pattern GP2 in the second direction DR2 may have a convex shape toward the display panel 110. The cross section of the second light guide pattern GP2 in the first direction DR1 may have a circular shape. The cross section of the second light guide pattern GP2 in the first direction DR1 may have one selected from a partial shape of a circle, an ellipse, etc.

The second light guide pattern GP2 may have a cross-sectional width that decreases from the end portion of the base substrate SB in the second direction DR2. Specifically, the cross section of the second light guide pattern GP2 in the first direction DR1 may vary in the second direction DR2.

For example, the cross section of the second light guide pattern GP2 in the first direction DR1, which is disposed on the end portion of the one side of the base substrate SB in the second direction DR2, may have a cross-sectional size (width) that decreases toward the other side in the second direction DR2. The cross section of the second light guide pattern GP2 in the first direction DR1, which is disposed on the end portion of the other side of the base substrate SB in the second direction DR2, may have a cross-sectional size (width) that decreases toward the one side in the second direction DR2.

Accordingly, between adjacent second light guide patterns GP2 in the first direction DR1, the base substrate SB may be exposed without being covered by the second light guide pattern GP2.

Because the second light guide pattern GP2 has a width that decreases toward a central portion of the base substrate SB and exposes at least a portion of the base substrate SB of the second display area DA2, light diffusion in the first direction DR1 by the second light guide pattern GP2 can be minimized. Light traveling at a narrow viewing angle through the base substrate SB exposed without being covered by the second light guide pattern GP2 can smoothly maintain a narrow viewing angle.

As shown in FIG. 7, when the second display area DA2 operates in the privacy mode, light may not be emitted from the second light source LS2, but may be emitted from the first light source LS1. Most of light L3 emitted from the first light source LS1 may pass through the base substrate SB in an area exposed without being covered by the second light guide pattern GP2. Accordingly, in the privacy mode, the light L3 emitted from the first light source LS1 can maintain the narrow viewing angle more smoothly.

That is, when the second display area DA2 of the display apparatus 1 operates in the privacy mode, the narrow viewing angle of the emitted light can be more smoothly maintained by the area exposed without being covered by the second light guide pattern GP2, and the quality of images and videos provided at the narrow viewing angle can be improved.

The second light guide pattern GP2 may diffuse light emitted from the second light source LS2 and incident on the second light guide plate 132 in the first direction DR1 through scattering, refraction, diffraction, total surface reflection, etc.

Since the cross section of the second light guide pattern GP2 is formed in a partial shape of a circle, an ellipse, or the like, light may be diffused in the first direction DR1 through the second light guide pattern GP2.

As shown in FIG. 8, when the second display area DA2 operates in the share mode, light may be emitted from the first light source LS1 and the second light source LS2. Some of light L4 emitted from the second light source LS2 may pass through the third light guide pattern GP3, may be refracted and reflected by the fourth light guide pattern GP4, and may travel toward the second light guide pattern GP2.

When some of the light L4 emitted from the second light source LS2 passes through the second light guide pattern GP2, some light L4 may be refracted and diffused to one side and the other side in the first direction DR1 by the second light guide pattern GP2. Accordingly, in the share mode, the light L4 emitted from the second light source LS2 may provide a wide viewing angle more smoothly.

In addition, although not shown in FIG. 8, the second light guide pattern GP2 may allow some of the light emitted from the first light source LS1 to be incident on the second light guide pattern GP2. In this case, the second light guide pattern GP2 may refract and diffuse the light emitted from the first light source LS1 to one side and the other side in the first direction DR1.

That is, when the second display area DA2 of the display apparatus 1 is driven in the share mode, the light emitted from the first light source LS1 and the second light source LS2 may provide a wide viewing angle more smoothly through the second light guide pattern GP2, and the quality of images and videos provided at the wide viewing angle can be improved.

Only the light L4 emitted from the second light source LS2 is shown in FIG. 8, but substantially the same description may also be applied to the light emitted from the first light source LS1.

Consequently, even when the second display area DA2 may be switched between the share mode and the privacy mode, the shape and arrangement of the second light guide pattern GP2 can minimize the degradation of the quality of the images and videos provided in both the share mode and the privacy mode.

In addition, the first light guide pattern GP1 may be disposed in the first display area DA1 that operates in only the share mode to improve the quality of images and videos provided at the wide viewing angle, and in the second display area DA2 that operates variably between the share and privacy modes, the second light guide pattern GP2 different from the first light guide pattern GP1 may be disposed to minimize degradation in the quality of images and videos provided at the wide and narrow viewing angles.

The third light guide pattern GP3 may be disposed on side surfaces of the base substrate SB. The third light guide pattern GP3 may protrude from the base substrate SB toward the second light source LS2. The third light guide pattern GP3 may be provided as a plurality of third light guide patterns. Each of the plurality of third light guide patterns GP3 may extend in the first direction DR1. The plurality of third light guide patterns GP3 may be disposed across the first display area DA1 and the second display area DA2. The plurality of third light guide patterns GP3 may be repeatedly disposed in the third direction DR3.

Light emitted from the second light source LS2 and incident on the third light guide pattern GP3 may be refracted to one side and the other side in the third direction DR3 while passing through the third light guide pattern GP3. The light emitted from the second light source LS2 may be guided upward from the base substrate SB through the third light guide pattern GP3.

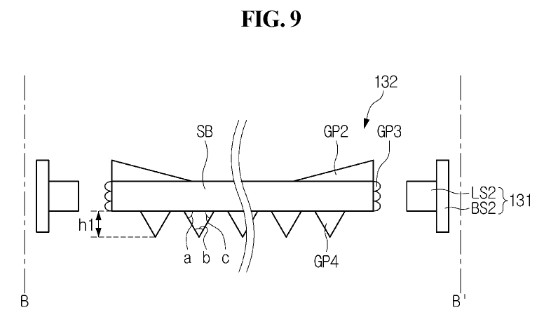

The fourth light guide pattern GP4 may be disposed on the lower surface (back surface) of the base substrate SB. The lower surface of the base substrate SB may be a surface facing the prism sheet 124. The fourth light guide pattern GP4 will be described in more detail with further reference to FIGS. 9 to 11.

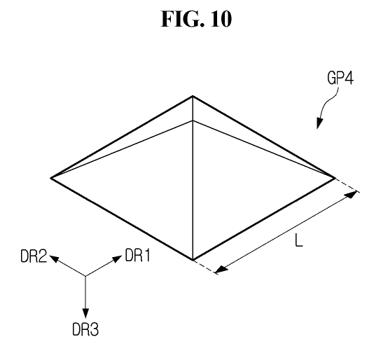

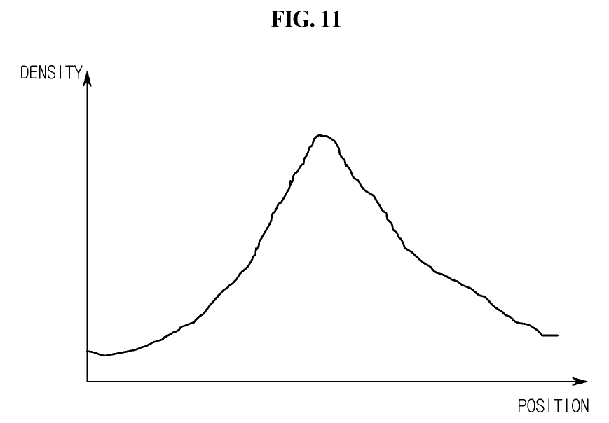

FIG. 9 is a cross-sectional view along line B-B’ in FIG. 6. FIG. 10 is a schematic view showing the fourth light guide pattern GP4 according to one embodiment. FIG. 11 is a graph showing the density of the fourth light guide pattern GP4 in the second direction according to one embodiment.

In FIG. 11, a horizontal axis (X-axis) indicates the position of the base substrate SB in the second direction DR2, and a vertical axis (Y-axis) indicates a density per unit area of the fourth light guide pattern GP4. That is, the horizontal axis (X-axis) indicates the position of the base substrate SB in the second direction DR2 from one side to the other side. The higher the density per unit area of the fourth light guide pattern GP4, the greater the number of fourth light guide patterns GP4 that may be disposed per unit area.

Referring further to FIGS. 9 to 11, polygonal protruding fourth light guide patterns GP4 may be formed on the lower surface (back surface) of the base substrate SB. The fourth light guide patterns GP4 may be embossed on the back surface of the base substrate SB through injection molding or printing. In another embodiment, the fourth light guide patterns GP4 may be engraved in the back surface of the base substrate SB.

In one embodiment, the fourth light guide patterns GP4 may have a pyramidal shape. In this case, the fourth light guide patterns GP4 may have a symmetrical shape in which slopes of all four side surfaces forming the pyramid are the same or substantially similar. Accordingly, since the light emitted from the second light source packages 131 disposed on the one side and the other side of the base substrate SB in the second direction DR2 can be uniformly refracted or dispersed to the one side and the other side in the first direction DR1, a portion of the display area DA corresponding to an area in which the second light source LS2 is turned on operates more smoothly in the share mode.

In one embodiment, a length “L” of one side of the symmetrical pyramid may range from about 10 to 50 μm, for example, about 30 μm. In addition, in one embodiment, an angle “a” between the back surface of the base substrate SB and one side surface of the symmetrical pyramid may range from about 20 to 60°, for example, about 40°. An angle “c” between the back surface of the second light guide plate 132 and the other side surface of the symmetrical pyramid may range from about 20 to 60°, for example, about 40°. A vertex angle “b” of the symmetrical pyramid may be about 100°.

The angle “a” between the back surface of the base substrate SB and the one side surface of the symmetrical pyramid and the angle “c” between the back surface of the base substrate SB and the other side surface of the symmetrical pyramid may be the same, but are not limited thereto.

A height h1 of the symmetrical pyramid may be determined depending on the size and slopes of four side surfaces and may, for example, range from 5 μm to 30 μm. However, the present embodiment is not limited thereto.

The light incident from the second light source package 131 to the second light guide plate 132 may have its emission angle controlled by the fourth light guide patterns GP4 formed on the back surface of the base substrate SB. Since the fourth light guide pattern GP4 is formed in a symmetrical pyramid shape or dot shape, the light emitted from the second light source packages 131 disposed on the one side and the other side of the second light guide plate 132 in the second direction DR2 may be refracted at the four surfaces or curved surfaces of the fourth light guide patterns GP4. Accordingly, the light emitted from the second light source package 131 may be refracted and emitted from the fourth light guide patterns GP4 both in the second direction DR2 and in the first direction DR1.

The light emitted from the second light source package 131 may be refracted and emitted to one side and the other side in the first direction DR1 by the fourth light guide pattern GP4 while passing through the second light guide plate 132, and the light emitted from the second light source package 131 may be emitted at a wide angle in the first direction DR1.

The fourth light guide patterns GP4 may be disposed to be regularly or irregularly spaced apart from each other. The density per unit area of the fourth light guide pattern GP4 may vary depending on the position of the second light guide plate 132.

The density per unit area of the fourth light guide pattern GP4 may vary in the second direction DR2.

As shown in FIG. 11, the density per unit area of the fourth light guide pattern GP4 on the base substrate SB may decrease toward the second light source package 131 and increase farther from the second light source package 131. As the second light source packages 131 are disposed on both the one side and the other side of the base substrate SB in the second direction DR2, the density per unit area of the fourth light guide pattern GP4 on the base substrate SB may increase toward a central portion in the second direction DR2 and decrease from the central portion toward the one side and the other side in the second direction DR2.

As the density per unit area of the fourth light guide pattern GP4 increases farther from the second light source package 131, even when the amount of light reaching a distant area from the second light source package 131 is insufficient, a percentage of light refracted or dispersed in the first direction DR1 by a greater number of light guide patterns GP4 may increase.

Accordingly, light passing through the second light guide plate 132 can be more uniform across the entire display area DA. Furthermore, the uniformity of luminance depending on the viewing angle of the display apparatus 1 can be improved.

The density per unit area of the fourth light guide pattern GP4 on the base substrate SB may be the same in the first direction DR1, but is not limited thereto.

Hereinafter, other embodiments of the invention will be described. For contents that are substantially the same as those described with reference to FIGS. 1 to 11 among components included in other embodiments, the same reference numerals are given, and overlapping contents may be omitted or briefly described.

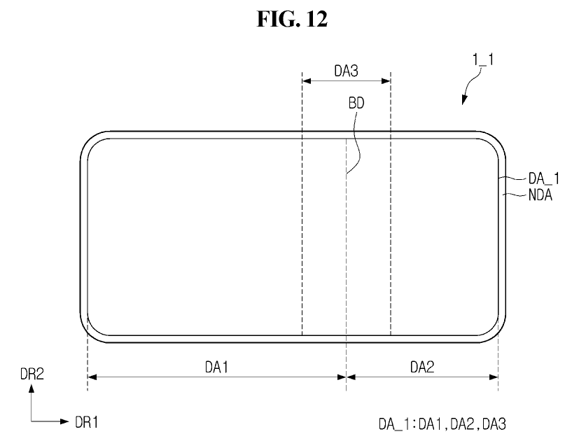

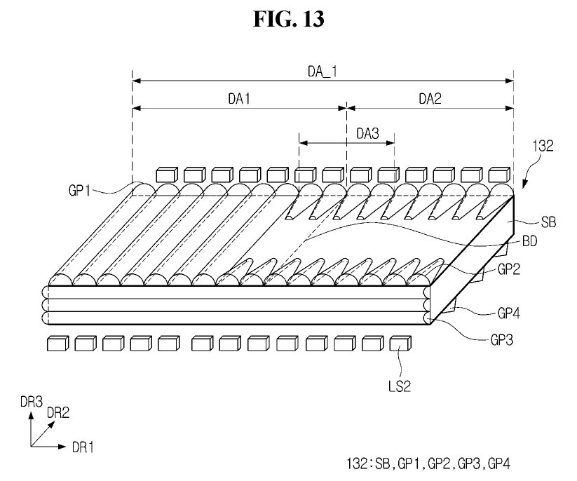

FIG. 12 is a plan view of the display apparatus according to another embodiment. FIG. 13 is a perspective view of a second light guide plate and its surroundings according to another embodiment.

Referring to FIGS. 12 and 13 , a display area DA_1 of a display apparatus 1_1 according to the present embodiment may include not only the first display area DA1 and the second display area DA2, but also a third display area DA3.

The third display area DA3 may overlap a portion of at least one of the first display area DA1 and the second display area DA2.

The display boundary BD, which is a boundary between the first display area DA1 and the second display area DA2, may be positioned within the third display area DA3. The display boundary BD may extend in the second direction DR2 and move from the third display area DA3 to one side or the other side in the first direction DR1. Depending on the position of the display boundary BD, at least one of the first display area DA1 and the second display area DA2 may overlap the third display area DA3.

Depending on the position of the display boundary BD, the sizes of the first display area DA1 and the second display area DA2 may vary.

Some of the plurality of second light sources LS2 disposed in at least some areas may be individually driven (turned on and off). Accordingly, the sizes of the first display area DA1 and the second display area DA2 may vary.

Depending on the second light source LS2 being turned on and off, the second display area DA2 may be switched between the privacy mode and the share mode. Accordingly, by adjusting the number and arrangement of second light sources LS2 being turned on among the second light sources LS2 corresponding to the third display area DA3, the display boundary BD, which is the boundary between the first display area DA1 and the second display area DA2, may be adjusted to one side and the other side in the first direction DR1.

Here, the second light sources LS2 corresponding to the third display area DA3 are the second light sources LS2 disposed on one side and the other side of the third display area DA3 in the second direction DR2 among the plurality of second light sources LS2.

That is, depending on the arrangement of the second light sources LS2 whose turn-on and turn-off states are switched, the sizes of the first display area DA1 and the second display area DA2 may vary, and the position of the display boundary BD, which is the boundary between the first display area DA1 and the second display area DA2, may vary.

In this case, since the second light source package 131 is disposed to face the long side of the second light guide plate 132, the sizes of the first display area DA1 and the second display area DA2 may vary more easily.

The first light guide pattern GP1 may be disposed on only the other side of the third display area DA3 in the first direction DR1. Even when the position of the display boundary BD varies, the first light guide pattern GP1 may be disposed on only a portion of the first display area DA1 that does not overlap the third display area DA3.

The second light guide pattern GP2 may be disposed across the second display area DA2 and the third display area DA3. Even when the position of the display boundary BD varies, the second light guide pattern GP2 may be disposed across the second display area DA2 and the third display area DA3 and may also be disposed at a position where the second display area DA2 overlaps the third display area DA3.

In the second display area DA2 and the third display area DA3, a portion of the base substrate SB may be exposed without being covered by the second light guide pattern GP2.

Because the sizes of the first display area DA1 and the second display area DA2 vary, the convenience of the user of the display apparatus 1_1 may be enhanced. Furthermore, the efficiency of the display apparatus 1_1 can be improved and the manufacturing process of the display apparatus 1_1 can be simplified, thereby reducing power consumption and production energy.

Even in this case, since the second light guide pattern GP2 is disposed across the second display area DA2 and the third display area DA3, even when the size of the second display area DA2 varies, it is possible to minimize the degradation of the quality of images and videos provided in both the share mode and the privacy mode.

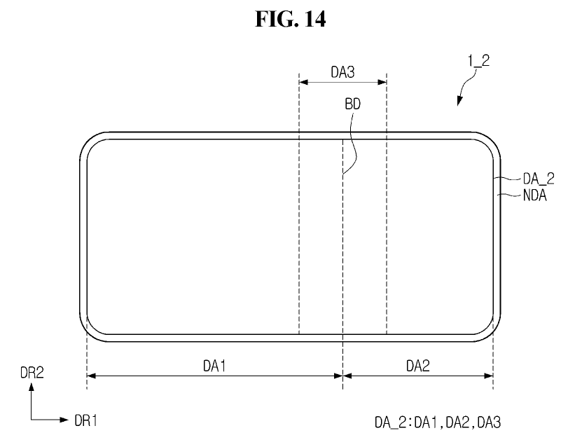

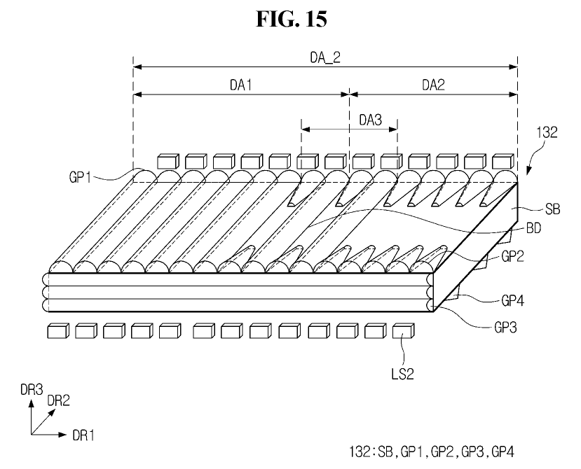

FIG. 14 is a plan view of the display apparatus according to another embodiment. FIG. 15 is a perspective view of a second light guide plate and its surroundings according to still another embodiment.

Referring to FIGS. 14 and 15 , a display area DA_2 of a display apparatus 1_2 according to the present embodiment includes the first display area DA1, the second display area DA2, and a third display area DA3, and the present embodiment differs from the embodiments of FIGS. 12 and 13 in that both the first light guide pattern GP1 and the second light guide pattern GP2 may be disposed in the third display area DA3.

Both the first light guide pattern GP1 and the second light guide pattern GP2 may be disposed in the third display area DA3 and may be alternately and repeatedly disposed in the first direction DR1, but is not limited thereto.

Only the first light guide pattern GP1 may be disposed in an area of the first display area DA1 that does not overlap the third display area DA3. Only the second light guide pattern GP2 may be disposed in an area of the second display area DA2 that does not overlap the third display area DA3.

As the first light guide pattern GP1 is additionally disposed in the third display area DA3, even when the sizes of the first display area DA1 and the second display area DA2 in the third display area DA3 vary, it is possible to minimize the degradation of the quality of images and videos provided at the wide viewing angle in the share mode operated in the third display area DA3.

Furthermore, since the second light guide pattern GP2 is also disposed, it is possible to minimize the degradation of the quality of images and videos provided at the narrow viewing angle in the privacy mode operated in the third display area DA3.

According to the embodiments of the invention, different images can be provided depending on the viewing angle.

According to the embodiments of the invention, the light guide patterns having different characteristics depending on the viewing angle can be disposed.

According to the embodiments of the invention, the light guide patterns having different characteristics depending on the viewing angle can be disposed, thereby improving the quality of images emitted at narrow and wide viewing angles.

According to the embodiments of the invention, it is possible to improve the quality of images emitted at narrow and wide viewing angles, thereby reducing the power consumption of the display apparatus.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a display area including a first display area and a second display area disposed in a first direction;
a plurality of first light sources disposed within the display area;
a diffusion sheet disposed on the plurality of first light sources;
a light control film disposed on the diffusion sheet;
a light guide plate disposed on the light control film and including a base substrate, a first light guide pattern and a second light guide pattern on the base substrate; and
a plurality of second light sources disposed to face side surfaces of the light guide plate,
wherein the first light guide pattern and the second light guide pattern have different shapes, the first light guide pattern is disposed in the first display area, and the second light guide pattern is disposed in the second display area.

2. The display apparatus of claim 1, wherein:
the first light guide pattern covers the entire first display area of the base substrate; and
the second light guide pattern covers a portion of the second display area of the base substrate and exposes the remaining portion.

3. The display apparatus of claim 2, wherein the second light guide pattern is disposed near an end portion of at least one of one side and the other side of the base substrate in a second direction intersecting the first direction.

4. The display apparatus of claim 3, wherein:
the second light guide pattern extends from the end portion of the base substrate in the second direction; and
a cross-sectional size of the second light guide pattern in the first direction decreases farther from the end portion of the base substrate.

5. The display apparatus of claim 4, wherein a cross-sectional size of the first light guide pattern in the first direction is constant in the second direction.

6. The display apparatus of claim 3, wherein the second light guide pattern comprises a plurality of second light guide patterns repeatedly disposed in the first direction.

7. The display apparatus of claim 6, wherein the first light guide pattern comprises a plurality of first light guide patterns repeatedly disposed in the first direction, and each of the plurality of first light guide patterns extends in the second direction.

8. The display apparatus of claim 1, wherein:
the first display area is configured to operate in a share mode with a wide viewing angle; and
the second display area is configured to variously operate between the share mode with the wide viewing angle and a privacy mode with a narrow viewing angle.

9. The display apparatus of claim 8, wherein:
when the second display area operates in a share mode, some of the plurality of second light sources corresponding to the second display area are turned on; and
when the second display area operates in the privacy mode, some of the plurality of second light sources corresponding to the second display area are turned off.

10. The display apparatus of claim 9, wherein:
the plurality of second light sources are repeatedly disposed in the first direction and disposed to face a side surface of at least one of one side and the other side of the light guide plate in the second direction; and
the second direction intersects the first direction.

11. The display apparatus of claim 1, wherein the first light guide pattern and the second light guide pattern are disposed on an upper surface of the base substrate.

12. The display apparatus of claim 11, further comprising a third light guide pattern disposed on a side surface of the base substrate,
wherein the third light guide pattern comprises a plurality of third light guide patterns, repeatedly disposed in a thickness direction of the light guide plate, and extends in the first direction.

13. The display apparatus of claim 12, wherein the plurality of third light guide patterns face the plurality of second light sources.

14. The display apparatus of claim 1, wherein the display area further includes a third display area in which a display boundary, which is a boundary between the first display area and the second display area, moves in the first direction.

15. The display apparatus of claim 14, wherein the third display area overlaps at least one of the first display area and the second display area.

16. The display apparatus of claim 15, wherein the second light guide pattern is disposed across the third display area and the second display area.

17. A display apparatus comprising:
a display area including a first display area and a second display area;
a plurality of first light sources disposed within the display area;
a diffusion sheet disposed on the plurality of first light sources;
a light control film disposed on the diffusion sheet;
a light guide plate disposed on the light control film and including a base substrate, a first light guide pattern and a second light guide pattern on the base substrate; and
a plurality of second light sources disposed to face side surfaces of the light guide plate,
wherein:
the first light guide pattern is disposed in the first display area, the second light guide pattern is disposed in the second display area; and
the second light guide pattern covers a portion of the second display area of the base substrate and exposes the remaining portion.

18. The display apparatus of claim 17, wherein the first light guide pattern covers the entire first display area of the base substrate.

19. The display apparatus of claim 18, wherein the first light guide pattern and the second light guide pattern have different shapes.

20. The display apparatus of claim 17, wherein:
the first display area is configured to operate in a share mode with a wide viewing angle; and
the second display area is configured to variously operate between the share mode with the wide viewing angle and a privacy mode with a narrow viewing angle.
